(19) United States
(12) Patent Application Publication
(10) Pub. No.: US 2018/0242448 A1
(43) Pub. Date: Aug. 23, 2018

(54) RESIN COMPOSITION, ADHESIVE FILM, COVERLAY FILM, LAMINATE, RESIN-COATED COPPER FOIL AND RESIN-COATED COPPER-CLAD LAMINATE

(71) Applicant: ARISAWA MFG. CO., LTD., Niigata (JP)

(72) Inventors: Kazuo YOSHIKAWA, Niigata (JP); Makoto TAI, Niigata (JP); Nobuyuki IWANO, Niigata (JP); Takayuki MAYAMA, Niigata (JP)

(21) Appl. No.: 15/896,166

(22) Filed: Feb. 14, 2018

(30) Foreign Application Priority Data
Feb. 20, 2017 (JP) 2017-029450

(51) Int. Cl. H05K 1/03; H05K 3/00; C08L 53/00; C08K 3/36; C09J 153/00; B32B 7/12; B32B 15/08; B32B 15/20

(52) U.S. Cl. CPC H05K 1/036; H05K 3/0035; C08L 53/005; C08K 3/36; H05K 1/024; B32B 7/12; B32B 15/08; B32B 15/20; C09J 153/005

(57) ABSTRACT

The present invention provides a resin composition comprising a specific styrene polymer, a specific inorganic filler, and a curing agent, wherein the styrene polymer is a specific acid-modified styrene polymer, and the resin composition satisfies specific conditions in the form of a film having a thickness of 25 μm.

### BACKGROUND OF THE INVENTION

### Field of the Invention

The present invention relates to a resin composition, an adhesive film, a coverlay film, a laminate, a resin-coated copper foil and a resin-coated copper-clad laminate.

### Description of the Related Art

In recent years, higher-frequency signals have been pursued as transmission signals in flexible printed circuits (FPC) have speeded up. Along with this, materials for FPC are further required to have low dielectric properties (low dielectric constant and low dielectric loss tangent) in high-frequency areas. Meanwhile, multilayer formation of 3 or more layers or decrease in the diameters of blind vias, etc. has been practiced in association with increase in the density of FPC. For this purpose, adhesives for bonding together various members of FPC are further required to have excellent low dielectric properties and excellent UV laser processability.

Japanese Patent Laid-Open No. 2016-135859 discloses a resin composition excellent in low dielectric loss tangent properties, containing a polyimide compound, a modified polybutadiene, and an inorganic filler.

Japanese Patent Laid-Open No. 6-13495 discloses a low dielectric resin composition provided with UV laser processability by adding a polyimide to a fluorine resin.

Japanese Patent Laid-Open No. 2004-175983 discloses a resin composition provided with UV laser processability by adding, to a fluorine resin, an ultraviolet absorbing substance comprising titanium oxide or zinc oxide surface-coated with alumina, silica, or stearic acid.

Japanese Patent Laid-Open No. 2006-63297 discloses an insulating resin composition having a low dielectric constant, comprising a low dielectric constant—imparting agent comprising a low dielectric constant—imparting component such as polystyrene or polyolefin filled in the pore part of a porous substance (silica), and an insulating resin composition.

### SUMMARY OF THE INVENTION

However, the resin compositions disclosed in Japanese Patent Laid-Open Nos. 2016-135859 and 6-13495 contain a polyimide and therefore have a high rate of water absorption. Therefore, these resin compositions deteriorate dielectric loss tangent properties under high humidity and cannot properly propagate transmission signals.

The resin composition disclosed in Japanese Patent Laid-Open No. 2004-175983 is composed mainly of a fluorine resin as a resin and therefore has excellent dielectric properties and a low rate of water absorption in an ordinary state. Hence, this resin composition can properly propagate transmission signals without deteriorating a dielectric loss tangent even under high humidity. However, the resin composition, which is composed mainly of the fluorine resin, has poor close contact. For this reason, this resin composition cannot be practically used as a material for FPC.

The resin composition disclosed in Japanese Patent Laid-Open No. 2006-63297 has an amount of the low dielectric constant—imparting component added as low as 46%. Furthermore, this resin composition is formed of an epoxy resin and a phenol resin and is therefore presumed to have a large proportion of hydroxy groups generated after curing and hydroxy groups of unreacted phenol resins. As a result, the dielectric constant of the composition after curing is 2.9 at best, which does not permit the resin composition to cope with the recent lower dielectric constant. Moreover, the resin composition after curing has a high rate of water absorption due to the large proportion of hydroxy groups and consequently deteriorates a dielectric loss tangent under a highly humid environment.

Accordingly, an object of the present invention is to provide a resin composition excellent in dielectric properties under high humidity, UV laser processability and close contact.

The present inventors have conducted diligent studies to attain the object and consequently completed the present invention by finding that the object can be attained by a resin composition comprising a specific styrene polymer, a specific inorganic filler, and a curing agent at a specific ratio and having a rate of light absorption and a haze value within specific ranges.

Specifically, the present invention is as follows:

[1]

A resin composition comprising:

a styrene polymer, an inorganic filler, and a curing agent, wherein

the styrene polymer is an acid-modified styrene polymer having a carboxyl group,

the inorganic filler is silica and/or aluminum hydroxide,

a particle size of the inorganic filler is 1 μm or less,

a content of the inorganic filler is 20 to 80 parts by mass with respect to 100 parts by mass of the styrene polymer, and

the resin composition satisfies following expressions (A) and (B) in a form of a film having a thickness of 25 μm:

X≤50 (A)

Y≥40 (B)

wherein X represents a rate of absorption of light having a wavelength of 355 nm (unit: %), and Y represents a haze value (unit: %).
[2]

The resin composition according to [1], wherein the acid-modified styrene polymer is an acid-modified styrene elastomer.

[3]

The resin composition according to [2], wherein a whole or a portion of unsaturated double bonds contained in the acid-modified styrene elastomer is hydrogenated.

[4]

The resin composition according to [2] or [3], wherein the acid-modified styrene elastomer is an acid modification product of a copolymer comprising a styrene polymer block and an ethylene-butylene polymer block.

[5]

The resin composition according to any of [2] to [4], wherein the acid-modified styrene elastomer is an acid modification product of a styrene-ethylene-butylene-styrene block copolymer.

[6]

The resin composition according to any of [1] to [5], wherein the curing agent is one or more curing agents selected from the group consisting of an epoxy resin, a carbodiimide compound, and an oxazoline compound.

[7]

The resin composition according to any of [1] to [6], wherein a dielectric constant of the resin composition after curing is less than 2.8, and a dielectric loss tangent of the resin composition after curing is less than 0.006.

[8]

An adhesive film comprising a resin composition according to any of [1] to [7].

[9]

The adhesive film according to [8], wherein the adhesive film after curing has a thickness of 2 to 200 μm.

[10]

A coverlay film having a laminated structure where an adhesive layer comprising a resin composition according to any of [1] to [9] and an electrically insulating layer are laminated.

[11]

A laminate having a laminated structure where an adhesive layer comprising a resin composition according to any of [1] to [7], an electrically insulating layer, and a copper foil are laminated, wherein

the adhesive layer has a first surface and a second surface facing the first surface,

the electrically insulating layer is laminated on the first surface of the adhesive layer, and the copper foil is laminated on the second surface of the adhesive layer.

[12]

A resin-coated copper foil having a laminated structure where an adhesive layer comprising a resin composition according to any of [1] to [7] and a copper foil are laminated.

[13]

A resin-coated copper-clad laminate having a laminated structure where an adhesive layer comprising a resin composition according to any of [1] to [7], an electrically insulating layer, and a copper foil are laminated, wherein

the electrically insulating layer has a first surface and a second surface facing the first surface,

the adhesive layer is laminated on the first surface of the electrically insulating layer, and the copper foil is laminated on the second surface of the electrically insulating layer.

[14]

The laminate according to [13], wherein when the laminate is subjected to following treatments (1) and (2), the largest length in a horizontal direction of a depression formed on a cut surface in a horizontal direction of a cut site is 5 μm or less:

(1) the copper foil is removed to form a removal site, and
(2) the removal site is irradiated with laser light having a wavelength of 355 nm to form the cut site in a vertical direction of the removal site.

The present invention can provide a resin composition excellent in dielectric properties under high humidity, close contact and UV laser processability.

### BRIEF DESCRIPTION OF THE DRAWINGS

FIG. 1 shows a diagram schematically illustrating a method for evaluating laser processability in Examples.

### DETAILED DESCRIPTION OF THE PREFERRED EMBODIMENTS

Hereinafter, the mode for carrying out the present invention (hereinafter, referred to as the “present embodiment”) will be described in detail. However, the present invention is not limited by the embodiments given below, and various changes or modifications can be made therein without departing from the spirit of the present invention.

The resin composition according to the present embodiment is a resin composition comprising a styrene polymer, an inorganic filler, and a curing agent, wherein the styrene polymer is an acid-modified styrene polymer having a carboxyl group, the inorganic filler is silica and/or aluminum hydroxide, the particle size of the inorganic filler is 1 μm or less, the content of the inorganic filler is 20 to 80 parts by mass with respect to 100 parts by mass of the styrene polymer, and the resin composition satisfies the following expressions (A) and (B) in the form of a film having a thickness of 25 μm:

X≤50 (A)

Y≥40 (B)

wherein X represents the rate of absorption of light having a wavelength of 355 nm (unit: %), and Y represents a haze value (unit: %).

### [Acid-Modified Styrene Polymer]

The resin composition according to the present embodiment comprises an acid-modified styrene polymer having a carboxyl group. The “acid-modified styrene polymer” described herein has a constitutional unit derived from an aromatic vinyl (e.g., styrene and α-methylstyrene, preferably styrene) and has a carboxyl group. The “carboxyl group” described herein conceptually encompasses an “anhydrous carboxyl group”.

Examples of the acid-modified styrene polymer include copolymers comprising a unit derived from the aromatic vinyl and a unit derived from an unsaturated carboxylic acid (e.g., unsaturated monocarboxylic acids such as acrylic acid and methacrylic acid, and unsaturated dicarboxylic acids such as fumaric acid, maleic acid, and itaconic acid), and copolymers comprising a unit derived from the aromatic vinyl and a unit derived from an unsaturated carboxylic anhydride (e.g., maleic anhydride and itaconic anhydride). These copolymers may further comprise units derived from monomers copolymerizable with the aromatic vinyl and the unsaturated carboxylic acid or the unsaturated carboxylic anhydride (e.g., α-olefin, conjugated diene, vinyl esters, vinyl ethers, esters of acrylic acid or methacrylic acid, and vinyl halides).

Specific examples of the acid-modified styrene polymer include acid-modified styrene elastomers, acid-modified ABS resins (acrylonitrile-butadiene-styrene resins modified with an acid such as maleic anhydride), and acid-modified AS resins (acrylonitrile-styrene resins modified with an acid such as maleic anhydride). Among them, an acid-modified styrene elastomer is preferred in view of a low dielectric constant and a low dielectric loss tangent. The “styrene elastomer” described herein has the same meaning as that of a styrene-alkylene copolymer.

Examples of the acid-modified styrene elastomer include, but are not particularly limited to, acid modification products of copolymers comprising an aromatic vinyl polymer block (e.g., a styrene polymer block) and a conjugated diene block (e.g., a butadiene block and an isoprene block).

The whole or a portion of unsaturated double bonds contained in the acid-modified styrene elastomer is preferably hydrogenated in view of a low dielectric constant and a low dielectric loss tangent. This tends to be able to reduce the influence of the presence of π electrons derived from the unsaturated double bonds on dielectric properties. Examples of the acid-modified styrene elastomer having a hydrogenation rate of 100% include (i) an acid modification product of a copolymer comprising an aromatic vinyl polymer block (e.g., a styrene polymer block) and an ethylene-butylene polymer block (e.g., an acid modification product of a styrene-ethylene-butylene-styrene block copolymer), (ii) an acid modification product of a copolymer comprising an aromatic vinyl polymer block (e.g., a styrene polymer block) and an ethylene-propylene polymer block, and (iii) an acid modification product of a copolymer comprising an aromatic vinyl polymer block (e.g., a styrene polymer block) and an isobutylene polymer block. Among them, (i) an acid modification product of a copolymer comprising an aromatic vinyl polymer block (preferably a styrene polymer block) and an ethylene-butylene polymer block is preferred, and an acid modification product of a styrene-ethylene-butylene-styrene block copolymer is more preferred, in view of flexibility.

In the resin composition of the present embodiment, these acid-modified styrene polymers are each used alone or used in combination of two or more thereof.

The proportion of the styrene-derived unit in the acid-modified styrene polymer is preferably 10 to 65% by weight, more preferably 15 to 60% by weight, further preferably 20 to 55% by weight. When the proportion of the styrene-derived unit is 65% by weight or less, flexibility as FPC tends to be further improved owing to the better flexibility of the resin composition. On the other hand, when the proportion of the styrene-derived unit is 10% by weight or more, the resin composition, when cured and used as an adhesive for FPC materials, tends to maintain the circuit and be less likely to cause disconnection in the circuit because the adhesive is prevented from being excessively softened and is less movable even upon bending.

The acid-modified styrene polymer contains a carboxyl group in the molecular chain (typically, in a side chain). The acid-modified styrene polymer, which contains a carboxyl group, reacts with a curing agent such as an epoxy compound or a carbodiimide compound to form a three-dimensional network structure, resulting in improvement in heat resistance. The carboxyl group equivalent of the acid-modified styrene polymer is preferably 11000 g/eq or less, more preferably 8000 g/eq or less, further preferably 6000 g/eq or less. When the carboxyl group equivalent is 11000 g/eq or less, there is a tendency to further improve cross-linking density and attain better solder reflow resistance. The carboxyl group equivalent can be measured in accordance with JIS K 1557-5. Specifically, the carboxyl group equivalent is measured by, for example, the following method: 200 mL of 2-propanol, 100 mL of water and 7 drops of a methanol solution of bromothymol blue are added, and the mixture is titrated until becoming green with a 0.02 mol/L solution of potassium hydroxide in methanol. 50 g of a sample is dissolved therein. This solution is titrated with a 0.02 mol/L solution of potassium hydroxide in methanol, and the carboxyl group equivalent is calculated according to the following expression:

Carboxyl group equivalent (g/eq)=(56100×3 (g/Amount of sample collected)/((1.122×(Titer mL)×0.02 (Titrant concentration))

### [Inorganic Filler]

The resin composition comprises an inorganic filler having a particle size of 1 μm or less (hereinafter, also referred to as a “specific inorganic filler”). In general, the acid-modified styrene polymer poorly absorbs UV-YAG laser light having a wavelength of 355 nm and is inferior in UV laser processability. In response to this, the resin composition, which contains the specific inorganic filler, can improve UV laser processability. The resin composition containing the inorganic filler cannot enhance the rate of absorption of light having a wavelength of 355 nm, but can improve a haze value (Diffused transmittance/Total light transmittance×100(%)). In this context, a large haze value means a large diffused transmittance and therefore allows light to sufficiently diffuse in and pass through the resin composition. As a result, UV laser comes into contact with the styrene polymer in a wider range to promote the abrasion of the styrene polymer.

The inorganic filler is preferably silica and/or aluminum hydroxide in view of a low dielectric constant and a low dielectric loss tangent.

The particle size of the inorganic filler is 1 μm or less, preferably 0.8 μm or less. If the particle size of the inorganic filler exceeds 1 μm, the particle size of the inorganic filler corresponds to a length on the order of 3 times the UV-YAG laser wavelength of 355 nm. Therefore, a haze value might be decreased, and laser processability might be insufficient.

The particle size of the inorganic filler can be measured on the basis of laser diffraction particle size distribution in accordance with JIS Z 8825 2013. Specifically, for example, the inorganic filler is prepared into slurry by addition to a dispersing solvent. Then, the slurry is gradually added to a measurement vessel of a laser diffraction flow distribution analyzer, and the concentration is adjusted such that the degree of light transmission is a reference. Subsequently, measurement is performed according to the automatic measurement of the apparatus.

The content of the inorganic filler is 20 to 80 parts by mass, preferably 30 to 70 parts by mass, more preferably 35 to 65 parts by mass, with respect to 100 parts by mass of the styrene polymer. When the content of the inorganic filler is 20 parts by mass or larger, laser processability is improved without decreasing a haze value. On the other hand, when the content of the inorganic filler is 80 parts by mass or less, a dielectric constant and a dielectric loss tangent are decreased.

The dielectric constant of the inorganic filler is not particularly limited and is preferably 10 or less, more preferably 8 or less, further preferably 5 or less.

### [Curing Agent]

The resin composition comprises a curing agent. The curing agent reacts with the carboxyl group contained in the styrene polymer to thereby increase cross-linking density and improve close contact power and solder reflow resistance.

The curing agent is not particularly limited as long as the curing agent is reactable with the carboxyl group. Examples thereof include epoxy resins, carbodiimide compounds, amine compounds, oxazoline compounds, and isocyanate compounds. Among them, an epoxy resin, a carbodiimide compound, and/or an oxazoline compound is preferred, and an epoxy resin is more preferred, in view of reactivity.

Examples of the epoxy resin include bisphenol A-type epoxy resins, bisphenol F-type epoxy resins, bisphenol S-type epoxy resins, novolac-type epoxy resins, biphenyl-type epoxy resins, cyclopentadiene-type epoxy resins, glycidylamine-type epoxy resins, and fused polycyclic epoxy resins.

The epoxy equivalent of the epoxy resin is preferably 500 g/eq or less, more preferably 300 g/eq or less. When the epoxy equivalent is 500 g/eq or less, a dielectric constant and a dielectric loss tangent tend to be better because the epoxy content in the resin composition can be small. The epoxy equivalent of the epoxy resin can be measured in accordance with JIS K 7236 2001.

The functional group equivalent of the curing agent with respect to 1 carboxyl group equivalent of the styrene polymer contained in the resin composition is preferably 0.3 to 3.0, more preferably 0.5 to 2.5, further preferably 0.7 to 2.0. When the functional group equivalent with respect to 1 carboxyl group equivalent is 0.3 or larger, there is a tendency to further improve reactivity and attain better solder reflow resistance. On the other hand, when the functional group equivalent with respect to 1 carboxyl group equivalent is 3.0 or less, there is a tendency to attain better insulation reliability and a better dielectric constant and dielectric loss tangent because the epoxy resin is not an excess.

The resin composition according to the present embodiment may comprise other additives in addition to each component mentioned above. Examples of other additives that may be used include various additives known in the art such as: hindered phenol, phosphorus, or sulfur antioxidants; stabilizers such as light stabilizers, weather stabilizers, and heat stabilizers; flame retardants such as triallyl phosphate and phosphoric acid ester; anionic, cationic, or nonionic surfactants; plasticizers; and lubricants. The amounts of the additives added can be appropriately adjusted without impairing the effects of the present invention.

### [Properties of Resin Composition]

The resin composition satisfies the following expressions (A) and (B) in the form of a film having a thickness of 25 μm:

X≤50 (A)

Y≥40 (B)

In the expressions, X represents the rate of absorption of light having a wavelength of 355 nm (unit: %), and Y represents a haze value (unit: %).

The haze value is preferably 50% or more, more preferably 60% or more, further preferably 70% or more. If the haze is less than 40%, UV laser processability might be poor because UV laser cannot come into contact with the styrene polymer in a wide range. The rate of light absorption and the haze value can be measured by methods described in Examples.

A cured product of the resin composition of the present embodiment is excellent in dielectric properties. The dielectric constant of the resin composition after curing is preferably less than 2.8, more preferably 2.75 or less, further preferably 2.70 or less. The dielectric loss tangent of the resin composition after curing is preferably less than 0.006, more preferably 0.005 or less, further preferably 0.004 or less.

The resin composition according to the present embodiment can be prepared into a form such as an adhesive film and then used as, for example, an adhesive for various members of flexible printed circuits (FPC). Hereinafter, the adhesive film and various members will be described.

### [Adhesive Film]

The adhesive film according to the present embodiment comprises the resin composition of the present embodiment. The adhesive film can be prepared, for example, by coating a mold release film with the resin composition. More specifically, the release treatment film of a PET (polyethylene terephthalate) film, a PP (polypropylene) film, a PE (polyethylene) film, or the like mold release-coated on at least one surface is coated with the resin composition and then dried into a semi-cured state (hereinafter, also referred to as a B-stage) under fixed conditions (temperature: 80 to 180° C., time: 2 to 10 minutes) to obtain an adhesive film. The thickness of the coated film differs depending on a purpose and can be on the order of 10 to 100 μm. Examples of the coating method include, but are not particularly limited to, methods using a comma coater, a die coater, or a gravure coater. The adhesive film in a completely cured state (C-stage) can be obtained by treating the B-stage adhesive film under fixed curing conditions (temperature: 160 to 180° C., pressure: 2 to 3 MPa, time: 30 to 60 minutes).

The thickness of the adhesive film after curing is preferably 2 to 200 μm, more preferably 5 to 150 μm, further preferably 10 to 100 μm. When the thickness of the adhesive film is 200 μm or less, foaming at the time of production tends to be able to be further suppressed. When the thickness of the adhesive film is 2 μm or larger, the smoothness of a processed surface can be further maintained. Properties, for example, circuit filling properties, close contact, and foldability tend to be better.

### [Coverlay Film]

The coverlay film of the present embodiment has a structure where an adhesive layer comprising the resin composition of the present embodiment and an electrically insulating layer are laminated.

In the case of using the coverlay film as a member of FPC, the electrically insulating layer plays a role in protecting a circuit, etc. formed on a wiring board. Examples of the material constituting the electrically insulating layer include, but are not particularly limited to, one or more resins selected from the group consisting of polyimide, a liquid crystal polymer, polyphenylene sulfide, syndiotactic polystyrene, polyethylene terephthalate, polyethylene naphthalate, polycarbonate, polybutylene terephthalate, polyether ether ketone, and a fluorine resin.

Examples of the fluorine resin for the electrically insulating layer include, but are not particularly limited to, one or more resins selected from the group consisting of polytetrafluoroethylene, a polytetrafluoroethylene-perfluoroalkyl vinyl ether copolymer, a tetrafluoroethylene-hexafluoropropylene copolymer, a difluoroethylene-trifluoroethylene copolymer, a tetrafluoroethylene-ethylene copolymer, polychlorotrifluoroethylene, and polyvinylidene fluoride.

### [Laminate]

The laminate of the present embodiment is a laminate having a laminated structure where an adhesive layer comprising the resin composition of the present embodiment, an electrically insulating layer, and a copper foil are laminated, wherein the adhesive layer has a first surface and a second surface facing the first surface, the electrically insulating layer is laminated on the first surface of the adhesive layer, and the copper foil is laminated on the second surface of the adhesive layer. The laminate of the present embodiment is excellent in dielectric properties under high humidity, UV laser processability and close contact because the adhesive layer comprises the resin composition of the present embodiment.

Alternatively, the laminate according to the present embodiment may be a double-sided copper-clad laminate having a structure where adhesive layers comprising the resin composition of the present embodiment, an electrically insulating layer, and copper foils are laminated, wherein the adhesive layers are laminated on both surfaces of the electrically insulating layer, and the copper foils are laminated on the surfaces opposite to the electrically insulating layer-laminated surfaces of the adhesive layers. The double-sided copper-clad laminate has a structure where an adhesive layer and a copper foil are further disposed on the surface opposite to the adhesive layer- and copper foil-laminated surface of an electrically insulating layer of a single-sided copper-clad laminate.

The laminate differs in the cured state of the adhesive layer from the coverlay film. Specifically, the cured state of the adhesive layer contained in the coverlay film is a B-stage, whereas the cured state of the adhesive layer contained in the laminate is a C-stage. The coverlay film is laminated with a laminate with a circuit formed thereon, and then, the adhesive layer is further cured into a C-stage, as mentioned later.

The thickness of the adhesive layer contained in the laminate is preferably 2 to 50 μm, more preferably 5 to 25 μm. When the thickness of the adhesive layer is 2 μm or larger, the adhesion between the electrically insulating layer and an adherend tends to be better. When the thickness of the adhesive layer is 50 μm or less, foldability (flexibility) tends to be better.

The laminate of the present embodiment is excellent in UV laser processability. Therefore, unnecessary scrape, etc. resulting from irradiation with UV laser light can be suppressed. Hence, when the laminate of the present embodiment is subjected to the following treatments (1) and (2), the largest length in the horizontal direction of a depression formed on the cut surface in the horizontal direction of a cut site is, for example, 5 μm or less, preferably 3 μm or less:

(1) the copper foil is removed to form a removal site, and
(2) the removal site is irradiated with laser light having a wavelength of 355 nm to form the cut site in the vertical direction of the removal site.

The resin-coated copper foil of the present embodiment has a laminated structure where an adhesive layer comprising the resin composition of the present embodiment and a copper foil are laminated. The resin-coated copper foil of the present embodiment is excellent in dielectric properties under high humidity, UV laser processability and close contact because the adhesive layer comprises the resin composition of the present embodiment.

### [Resin-Coated Copper-Clad Laminate]

The resin-coated copper foil of the present embodiment is a resin-coated copper-clad laminate having a laminated structure where an adhesive layer comprising the resin composition of the present embodiment, an electrically insulating layer, and a copper foil are laminated, wherein the electrically insulating layer has a first surface and a second surface facing the first surface, the adhesive layer is laminated on the first surface of the electrically insulating layer, and the copper foil is laminated on the second surface of the electrically insulating layer. The resin-coated copper-clad laminate of the present embodiment is excellent in dielectric properties under high humidity, UV laser processability and close contact because the adhesive layer comprises the resin composition of the present embodiment.

In each member mentioned above, a separate film may be further laminated on an adhesive layer-exposed surface. Examples of the resin constituting the separate film include, but are not particularly limited to, one or more resins selected from the group consisting of a polyethylene terephthalate resin, a polyethylene naphthalate resin, a polypropylene resin, a polyethylene resin, and a polybutylene terephthalate resin. Among them, one or more resins selected from the group consisting of a polypropylene resin, a polyethylene resin, and a polyethylene terephthalate resin are preferred in view of reducing production cost. Each member having the separate film is used such that this separate film is detached therefrom and then the adhesive layer surface is attached to an adherend.

### [Flexible Printed Circuit]

The flexible printed circuit comprises the coverlay film of the present embodiment and a laminate and is obtained by forming a circuit on a copper foil contained in the laminate and then attaching the adhesive layer of the coverlay film to the circuit-formed surface of the laminate.

### [Production Method]

The method for producing each member according to the present embodiment is not particularly limited, and a method known in the art can be used. The coverlay film of the present embodiment can be produced by, for example, a method comprising the following step (a):

(a) coating one surface of an electrically insulating layer with varnish of the resin composition for adhesive layer formation, followed by drying into a B-stage.

The method for producing the single-sided copper-clad laminate according to the present embodiment further comprises, for example, the following step (b) in addition to the step (a):

(b) hot-pressing a copper foil to the adhesive layer-disposed surface of the coverlay film obtained in the step (a), and drying the adhesive layer into a C-stage.

The method for producing the double-sided copper-clad laminate according to the present embodiment can involve laminating an adhesive layer and a copper foil onto another surface of the electrically insulating layer of the single-sided copper-clad laminate in the same way as above.

Examples of the solvent for use in the varnish include acetone, toluene, methyl ethyl ketone, methyl isobutyl ketone, cyclohexanone, propylene glycol monomethyl ether, dimethylacetamide, butyl acetate, and ethyl acetate. The amount of the solvent added may be on the order of 300 to 500 parts by mass with respect to 100 parts by mass of the acid-modified styrene polymer.

The method for coating with the varnish can appropriately adopt a comma coater, a die coater, a gravure coater, or the like according to a coating thickness. The drying of the varnish can be carried out with an in-line dryer or the like. The conditions for this drying can be appropriately adjusted according to the types and amounts, etc. of resins and additives.

The resin-coated copper foil according to the present embodiment has a structure where an adhesive layer comprising the resin composition of the present embodiment and a copper foil are laminated. The resin-coated copper-clad laminate according to the present embodiment has a structure where an adhesive layer comprising the low dielectric resin composition mentioned above, an electrically insulating layer, and a copper foil are laminated, wherein the adhesive layer is laminated on the first surface of the electrically insulating layer, and the copper foil is laminated on the second surface thereof. The resin-coated copper foil and the resin-coated copper-clad laminate can be produced in accordance with the method for producing the coverlay or the copper-clad laminate mentioned above.

The measurement and evaluation of each physical property described herein can be performed in accordance with methods described in Examples below, unless otherwise specified.

### EXAMPLES

Hereinafter, the present invention will be described further specifically with reference to Examples and Comparative Examples. However, the present invention is not intended to be limited by these Examples.

The following components and materials were used in Examples and Comparative Examples.

### [Styrene Polymer]

### (1) Styrene Polymer A

Tuftec M1913 manufactured by Asahi Kasei Chemicals Corp.

Hydrogenated styrene-ethylene-butylene-styrene block copolymer, carboxyl group equivalent: 5400 g/eq, proportion of a styrene-derived unit: 30% by weight.

### (2) Styrene Polymer B

Tuftec H1041 manufactured by Asahi Kasei Chemicals Corp.

Hydrogenated styrene-ethylene-butylene-styrene block copolymer, carboxyl group: absent, proportion of a styrene-derived unit: 30% by weight.

### (3) Styrene Polymer C

Asaprene 1-432 manufactured by Asahi Kasei Chemicals Corp.

Styrene-Butadiene-Styrene Block Copolymer, Carboxyl group: absent, proportion of a styrene-derived unit: 30% by weight.
[Inorganic filler]

### (1) Silica A

SC2050-MB manufactured by Admatech Inc., particle size: 0.5 μm.

### (2) Aluminum Hydroxide A

HIGILITE H-43 manufactured by Showa Denko K.K., particle size: 0.75 μm.

### (3) Silica B

VX-SR manufactured by Tatsumori Ltd., particle size: 2.5 μm.

### (4) Aluminum Hydroxide B

B-303 manufactured by Almorix Ltd., particle size: 4.3 μm.

### (5) Titanium Oxide

Ti-Pure R-960 manufactured by The Chemours Company, particle size: 0.5 μm.

### (6) Talc

D-600 manufactured by Nippon Talc Co., Ltd., particle size: 0.6 μm.

### (7) Organic Phosphorus Filler

OP930 manufactured by Clariant International Ltd., particle size: 3.5 μm.

### [Curing Agent]

### (1) Epoxy Resin

jER YX8800 manufactured by Mitsubishi Chemical Corp., fused polycyclic epoxy resin, epoxy equivalent: 180 g/eq.

### (2) Carbodiimide Compound

CARBODILITE V-05 manufactured by Nisshinbo Chemical Inc., carbodiimide equivalent: 262 g/eq.

### (3) Oxazoline Compound

1,3-PBO manufactured by Mikuni Pharmaceutical Industrial Co., Ltd., oxazoline equivalent: 108 g/eq.

In Examples and Comparative Examples, the measurement and evaluation of each physical property were performed by the following methods.

### [Peel Strength]

### (1) Sample Preparation Procedures

The mold release surface of a PET film of 38 μm in thickness mold release-coated on one surface was coated with a resin composition and dried into a semi-cured state (B-stage) under conditions of 80 to 180° C. and 1 to 30 minutes such that the thickness after drying was 25 μm, to form an adhesive layer (adhesive film).

A polyimide film having a thickness of 25 μm was laminated onto one surface of the adhesive layer, and the PET film was detached therefrom. Next, the gloss surface of a rolled copper foil (manufactured by JX Nippon Mining & Metals Corp., trade name: BHY-22B-T, thickness: 35 μm) was laminated onto the other surface facing the one surface of the adhesive layer, and heated and pressurized under conditions of 160° C., 3.0 MPa (pressure per cm²), and 60 minutes to obtain a sample (laminate).

### (2) Measurement Method

The sample prepared in (1) was cut into 10 mm in width×100 mm in length, and the peel strength in the direction of 90° (direction intersecting the surface direction of the laminate) was measured under the following measurement conditions using Autograph AGS-500 manufactured by Shimadzu Corp. The measurement conditions involved pulling of the base film and a test speed of 50 mm/min. The sample was evaluated according to the following criteria:

A: The peel strength was 7 N/cm or more.

B: The peel strength was 5 N/cm or more and less than 7 N/cm.

C: The peel strength was less than 5 N/cm.

### [Solder Reflow Resistance]

### (1) Sample Preparation Procedures

A laminate was prepared according to [Peel strength] (1) Sample preparation procedures.

### (2) Sample Used in Evaluation

Two types of laminates were used: the laminate described above and a heat-moisture-treated laminate prepared by storing the laminate under conditions of 40° C. and 90% RH for 96 hours. Each laminate was cut into a size of 50 mm×50 mm, and the resultant was used as a sample. Hereinafter, the former is referred to as an untreated sample, and the latter is referred to as a treated sample.

### (3) Measurement Method

The untreated sample and the treated sample were delivered into a solder reflow furnace set to 260° C. in terms of a peak temperature. In this operation, the delivery speed was set to 300 mm/min, and the exposure time of the peak temperature was adjusted to 10 seconds. The solder reflow resistance was evaluated by visually confirming the presence or absence of swelling and peeling of each sample after passing through the reflow furnace. The sample was evaluated according to the following criteria:

A: Neither swelling nor peeling was observed.

C: At least one of swelling and peeling was observed.

### [Insulation Reliability]

### (1) Sample Preparation

The mold release surface of a PET film of 38 μm in thickness mold release-coated on one surface was coated with a resin composition and dried into a semi-cured state (B-stage) under conditions of 80 to 180° C. and 1 to 30 minutes such that the thickness after drying was 25 μm, to form an adhesive layer (adhesive film).

A polyimide film having a thickness of 25 μm was laminated onto one surface of the adhesive layer to obtain a sample.

### (2) Adherend Preparation

The adherend used was prepared by forming a circuit pattern of pattern line width (L)/space (S)=50/50 on the copper foil gloss surface of a two-layer substrate composed of an electrolytic copper foil (manufactured by JX Nippon Mining & Metals Corp., thickness: 18 μm) and a polyimide layer of 25 μm in thickness formed on the rough surface of the electrolytic copper foil.

### (3) Evaluation Method

The PET mold release film was detached from the sample, and the other surface facing the one surface of the adhesive layer and the circuit-formed surface of the adherend were laminated by press molding (heating temperature: 160° C., heating time: 1 hour, pressure: 3 MPa). Then, the insulation reliability of the laminated sample was evaluated by visually confirming the presence or absence of a short circuit after 1000 hours under conditions of 85° C., 85% RH, and DC 50 V. The sample was evaluated according to the following criteria:

A: The short circuit was absent even after 1000 hours.

C: The short circuit occurred before reaching 1000 hours.

### [Dielectric Constant and Dielectric Loss Tangent]

### (1) Sample Preparation

The mold release surface of a PET film of 38 μm in thickness mold release-coated on one surface was coated with a resin composition and dried into a semi-cured state (B-stage) under conditions of 80 to 180° C. and 1 to 30 minutes such that the thickness after drying was 25 μm, to form an adhesive layer (adhesive film).

One surface (adhesive layer-exposed surface) of the adhesive layer and the mold release surface of a 38 μm PET film mold release-coated on one surface were laminated so as to face each other, followed by press molding (heating temperature: 160° C., heating time: 1 hour, pressure: 3 MPa) to obtain a sample. The PET mold release films on both sides were detached therefrom before use, and measurement was performed.

### (2) Measurement Method

The dielectric constant and the dielectric loss tangent were measured under conditions of a frequency of 5 GHz in an atmosphere of 23° C. using Network Analyzer N5230A SPDR (resonator method) manufactured by Agilent Technologies, Inc., and evaluated as given below. Also, a heat-moisture-treated sample prepared by storage for 96 hours under conditions of 40° C. and 90% RH was similarly evaluated. The sample was evaluated according to the following criteria:

(Dielectric Constant)

A: Less than 2.7
B: 2.7 or more and less than 2.8
C: 2.8 or more

(Dielectric Loss Tangent)

A: Less than 0.004
B: 0.004 or more and less than 0.006
C: 0.006 or more

### [Rate of Water Absorption]

### (1) Sample Preparation

A sample was obtained according to [Dielectric constant and dielectric loss tangent] (1) Sample preparation procedures. The PET mold release films were detached therefrom before use, and measurement was performed.

### (2) Measurement Method

The sample was dried under conditions of 105° C. and 0.5 hours and cooled to room temperature, and the mass of the resulting sample was defined as an initial value (m₀). This sample was dipped in pure water of 23° C. for 24 hours, and the mass (m_{d}) of the resulting sample was measured. From the initial value and the mass after the dipping, the rate of water absorption was measured according to the following expression:

(m_{d}−m₀)×100/m₀=Rate of water absorption (%)

A: The rate of water absorption was 0.5% or less.

B: The rate of water absorption was more than 0.5% and less than 1.0%.

C: The rate of water absorption was 1.0% or more.

### [Laser Processability]

### (1) Sample Preparation

The mold release surface of a PET film of 38 μm in thickness mold release-coated on one surface was coated with a resin composition and dried into a semi-cured state (B-stage) under conditions of 80 to 180° C. and 1 to 30 minutes such that the thickness after drying was 25 μm, to form an adhesive layer (adhesive film).

The single-sided copper-clad laminate and the double-sided copper-clad laminate used as adherends were PNS H0512RAH (12.5 μm polyimide and 12 μm rolled copper foil) and PKRW 1012EDR (25 μm polyimide and 12 μm electrolytic copper foil), respectively, manufactured by Arisawa Manufacturing Co., Ltd.

The single-sided copper-clad laminate was laminated onto the adhesive layer such that one surface of the adhesive layer and the polyimide layer of the single-sided copper-clad laminate faced each other. Then, the mold release film was detached therefrom, and the other surface facing the one surface of the adhesive layer and the double-sided copper-clad laminate were laminated, and heated and pressurized under conditions of 160° C., 3.0 MPa (pressure per cm²), and 60 minutes to obtain a sample.

### (2) Measurement Method

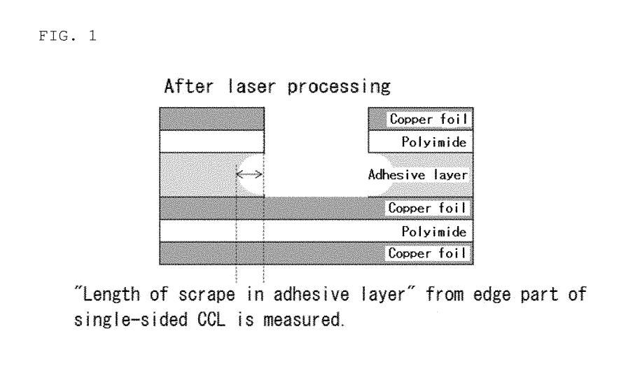

The copper foil part of the single-sided copper-clad laminate was conformally etched using UV-YAG laser Model 5330 manufactured by ESI Japan Ltd. Then, a blind via was created up to the boundary between the adhesive film and the double-sided copper-clad laminate (see FIG. 1). The cross section of the blind via part was observed under an optical microscope to measure the length of scrape of the adhesive layer (i.e., the largest length in the horizontal direction of a depression formed on the cut surface in the horizontal direction of a cut site).

### [Rate of Absorption and Haze]

### (1) Sample Preparation

A sample was obtained according to [Dielectric constant and dielectric loss tangent] (1) Sample preparation procedures. The PET mold release films were detached therefrom before use, and measurement was performed.

### (2) Measurement Method

The total light transmittance, reflectance, and diffused transmittance of light of 355 nm were measured using a spectrophotometer U-4100 manufactured by Hitachi High-Tech Science Corp. The rate of absorption and the haze value were calculated according to the following expressions:

Rate of absorption (%)=100−Total light transmittance (%)−Reflectance (%)

Haze value (%)=Diffused transmittance/Total light transmittance×100(%)

### Example 1

6.1 parts by mass of an epoxy resin (jER YX8800), 50 parts by mass of silica having a particle size of 0.5 μm (SC2050-MB), and 400 parts by mass of toluene as a dissolving solvent were added to 100 parts by mass of a hydrogenated styrene elastomer (Tuftec M1913), and the mixture was stirred to prepare adhesive varnish (resin composition).

### Examples 2 to 8 and Comparative Examples 1 to 9

Each adhesive varnish (resin composition) was obtained in the same way as in Example 1 except that the type and content of each component were changed as shown in Tables 1 and 2.

Various evaluations were conducted using the adhesive varnish (resin composition) of each of Examples 1 to 8 and Comparative Examples 1 to 9. The evaluation results are shown in Tables 1 and 2.

TABLE 1

| | | | Example | | | | | |
|---|---|---|---|---|---|---|---|---|
| | | | 1 | 2 | 3 | 4 | 5 | 6 |
| Styrene | Styrene | part by | 100 | 100 | 100 | 100 | 100 | 100 |
| polymer | polymer A | mass | | | | | | |
| Filler | Silica A | part by | 50 | 25 | 75 | — | 50 | 50 |
| | | mass | | | | | | |
| | Aluminum | | — | — | — | — | — | — |
| | hydroxide A | | | | | | | |
| Curing | Epoxy resin | equivalent | 1.8 | 1.8 | 1.8 | 1.8 | 0.5 | 2.5 |
| agent | | part by | 6.1 | 6.1 | 6.1 | 6.1 | 1.7 | 8.3 |
| | | mass | | | | | | |
| | Carbo- | equivalent | — | — | — | — | — | — |
| | diimide | part by | — | — | — | — | — | — |
| | compound | mass | | | | | | |
| | Oxazoline | equivalent | — | — | — | — | — | — |
| | compound | part by | — | — | — | — | — | — |
| | | mass | | | | | | |
| Peel | | Evaluation | A | A | B | B | A | B |
| strength | | | | | | | | |
| Solder | Ordinary | | A | A | A | A | A | A |
| reflow | state | | | | | | | |
| resistance | After heat- | | A | A | A | A | A | A |
| | moisture | | | | | | | |
| | treatment | | | | | | | |
| Insulation | | | A | A | A | A | A | A |
| reliability | | | | | | | | |
| Dielectric | Ordinary | | 2.60 | 2.56 | 2.70 | 2.72 | 2.58 | 2.64 |
| constant | state | | | | | | | |
| | After heat- | | 2.60 | 2.56 | 2.70 | 2.72 | 2.58 | 2.65 |
| | moisture | | | | | | | |
| | treatment | | | | | | | |
| Di- | Ordinary | | 0.0030 | 0.0024 | 0.0041 | 0.0048 | 0.0028 | 0.0035 |
| electric | state | | | | | | | |
| loss | After heat- | | 0.0031 | 0.0025 | 0.0042 | 0.0049 | 0.0029 | 0.0038 |
| tangent | moisture | | | | | | | |
| | treatment | | | | | | | |
| Rate | | | A | A | A | A | A | A |
| of water | | | | | | | | |
| absorption | | | | | | | | |
| Laser | μm | | 3 | 7 | 2 | 7 | 3 | 3 |
| process- | | | | | | | | |
| ability | | | | | | | | |
| Rate of | % | | 40 | 39 | 40 | 36 | 40 | 40 |
| absorption | | | | | | | | |
| Haze | % | | 71 | 57 | 75 | 55 | 70 | 70 |
| | | | | | | | Example | |
| | | | | | | | 7 | 8 |
| | | | | Styrene | Styrene | part by | 100 | 100 |
| | | | | polymer | polymer A | mass | | |
| | | | | Filler | Silica A | part by | 50 | 50 |
| | | | | | | mass | | |
| | | | | | Aluminum | | — | — |
| | | | | | hydroxide A | | | |
| | | | | Curing | Epoxy resin | equivalent | — | — |
| | | | | agent | | part by | — | — |
| | | | | | | mass | | |
| | | | | | Carbo- | equivalent | 1.8 | — |
| | | | | | diimide | part by | 8.7 | — |
| | | | | | compound | mass | | |
| | | | | | Oxazoline | equivalent | — | 1.8 |
| | | | | | compound | part by | — | 3.6 |
| | | | | | | mass | | |
| | | | | Peel | | Evaluation | A | A |
| | | | | strength | | | | |
| | | | | Solder | Ordinary | | A | A |
| | | | | reflow | state | | | |
| | | | | resistance | After heat- | | A | A |
| | | | | | moisture | | | |
| | | | | | treatment | | | |
| | | | | Insulation | | | A | A |
| | | | | reliability | | | | |
| | | | | Dielectric | Ordinary | | 2.63 | 2.59 |
| | | | | constant | state | | | |
| | | | | | After heat- | | 2.64 | 2.59 |
| | | | | | moisture | | | |
| | | | | | treatment | | | |
| | | | | Di- | Ordinary | | 0.0034 | 0.0029 |
| | | | | electric | state | | | |
| | | | | loss | After heat- | | 0.0037 | 0.0031 |
| | | | | tangent | moisture | | | |
| | | | | | treatment | | | |
| | | | | Rate | | | A | A |
| | | | | of water | | | | |
| | | | | absorption | | | | |
| | | | | Laser | μm | | 3 | 3 |
| | | | | process- | | | | |
| | | | | ability | | | | |
| | | | | Rate of | % | | 40 | 40 |
| | | | | absorption | | | | |
| | | | | Haze | % | | 70 | 71 |

TABLE 2

| | | | Comparative Example | | | | | | | | |
|---|---|---|---|---|---|---|---|---|---|---|---|
| | | | 1 | 2 | 3 | 4 | 5 | 6 | 7 | 8 | 9 |
| Styrene | Styrene | part by | — | — | 100 | 100 | 100 | 100 | 100 | 100 | 100 |
| polymer | polymer A | mass | | | | | | | | | |
| | Styrene | | 100 | — | — | — | — | — | — | — | — |
| | polymer B | | | | | | | | | | |
| | Styrene | | — | 100 | — | — | — | — | — | — | — |
| | polymer C | | | | | | | | | | |
| Filler | Silica A | part by | 50 | 50 | 10 | 90 | — | — | — | — | — |
| | Silica B | mass | — | — | — | — | 50 | — | — | — | — |
| | Aluminum | | — | — | — | — | — | 50 | — | — | — |
| | hydroxide B | | | | | | | | | | |
| | Titanium oxide | | — | — | — | — | — | — | 50 | — | — |
| | Talc | | — | — | — | — | — | — | — | 50 | — |
| | Organo- | | — | — | — | — | — | — | — | — | 50 |
| | phosphorus | | | | | | | | | | |
| | filler | | | | | | | | | | |
| Curing | Epoxy resin | equivalent | — | — | 1.8 | 1.8 | 1.8 | 1.8 | 1.8 | 1.8 | 1.8 |
| agent | | part by | 6.1 | 6.1 | 6.1 | 6.1 | 6.1 | 6.1 | 6.1 | 6.1 | 6.1 |
| | | mass | | | | | | | | | |
| Peel | | Evaluation | B | B | A | B | B | B | B | B | B |
| strength | | | | | | | | | | | |
| Solder | Ordinary state | | C | C | A | A | A | A | A | A | A |
| reflow | After heat- | | C | C | A | A | A | A | A | A | A |
| resistance | moisture | | | | | | | | | | |
| | treatment | | | | | | | | | | |
| Insulation | | | C | C | A | A | A | A | A | A | A |
| reliability | | | | | | | | | | | |
| Dielectric | Ordinary state | | 2.81 | 2.89 | 2.52 | 2.81 | 2.71 | 2.82 | 2.99 | 2.72 | 2.71 |
| constant | After heat- | | 2.84 | 2.96 | 2.52 | 2.81 | 2.71 | 2.84 | 2.99 | 2.84 | 2.75 |
| | moisture | | | | | | | | | | |
| | treatment | | | | | | | | | | |
| Dielectric | Ordinary state | | 0.0061 | 0.0068 | 0.0021 | 0.0062 | 0.0045 | 0.0052 | 0.0075 | 0.0044 | 0.0042 |
| loss | After heat- | | 0.0069 | 0.0077 | 0.0021 | 0.0062 | 0.0045 | 0.0054 | 0.0075 | 0.0045 | 0.0051 |
| tangent | moisture | | | | | | | | | | |
| | treatment | | | | | | | | | | |
| Rate | | | B | B | A | A | A | A | A | A | B |
| of water | | | | | | | | | | | |
| absorption | | | | | | | | | | | |
| Laser | μm | | 3 | 3 | 13 | 2 | 12 | 12 | 12 | 12 | 12 |
| process- | | | | | | | | | | | |
| ability | | | | | | | | | | | |
| Rate of | % | | 40 | 42 | 39 | 40 | 38 | 37 | 10 | 40 | 30 |
| absorption | | | | | | | | | | | |
| Haze | % | | 71 | 70 | 40 | 80 | 20 | 15 | 35 | 30 | 20 |

The results of Examples described above demonstrated that the resin composition of the present embodiment is excellent in dielectric properties under high humidity and is also excellent in close contact and UV laser processability.

The present application is based on Japanese Patent Application No. 2017-029450 filed on Feb. 20, 2017 and Japanese Patent Application No. 2018-008192 filed on Jan. 22, 2018, the contents of which are incorporated herein by reference in their entirety.

The low dielectric resin composition of the present invention has industrial applicability as an adhesive film or the like for use in flexible printed circuits.

What is claimed is:

1. A resin composition comprising:
a styrene polymer, an inorganic filler, and a curing agent, wherein
the styrene polymer is an acid-modified styrene polymer having a carboxyl group,
the inorganic filler is silica and/or aluminum hydroxide,
a particle size of the inorganic filler is 1 μm or less,
a content of the inorganic filler is 20 to 80 parts by mass with respect to 100 parts by mass of the styrene polymer, and
the resin composition satisfies following expressions (A) and (B) in a form of a film having a thickness of 25 μm:
X≤50 (A)
Y≥40 (B)
wherein X represents a rate of absorption of light having a wavelength of 355 nm (unit: %), and Y represents a haze value (unit: %).

2. The resin composition according to claim 1, wherein the acid-modified styrene polymer is an acid-modified styrene elastomer.

3. The resin composition according to claim 2, wherein a whole or a portion of unsaturated double bonds contained in the acid-modified styrene elastomer is hydrogenated.

4. The resin composition according to claim 1, wherein the acid-modified styrene elastomer is an acid modification product of a copolymer comprising a styrene polymer block and an ethylene-butylene polymer block.

5. The resin composition according to claim 1, wherein the acid-modified styrene elastomer is an acid modification product of a styrene-ethylene-butylene-styrene block copolymer.

6. The resin composition according to claim 1, wherein the curing agent is one or more curing agents selected from the group consisting of an epoxy resin, a carbodiimide compound, and an oxazoline compound.

7. The resin composition according to claim 1, wherein a dielectric constant of the resin composition after curing is less than 2.8, and a dielectric loss tangent of the resin composition after curing is less than 0.006.

8. An adhesive film comprising a resin composition according to claim 1.

9. The adhesive film according to claim 8, wherein the adhesive film after curing has a thickness of 2 to 200 μm.

10. A coverlay film having a laminated structure where an adhesive layer comprising a resin composition according to claim 1 and an electrically insulating layer are laminated.

11. A laminate having a laminated structure where an adhesive layer comprising a resin composition according to claim 1, an electrically insulating layer, and a copper foil are laminated, wherein
the adhesive layer has a first surface and a second surface facing the first surface,
the electrically insulating layer is laminated on the first surface of the adhesive layer, and the copper foil is laminated on the second surface of the adhesive layer.

12. A resin-coated copper foil having a laminated structure where an adhesive layer comprising a resin composition according to claim 1 and a copper foil are laminated.

13. A resin-coated copper-clad laminate having a laminated structure where an adhesive layer comprising a resin composition according to claim 1, an electrically insulating layer, and a copper foil are laminated, wherein
the electrically insulating layer has a first surface and a second surface facing the first surface,
the adhesive layer is laminated on the first surface of the electrically insulating layer, and the copper foil is laminated on the second surface of the electrically insulating layer.

14. The laminate according to claim 13, wherein when the laminate is subjected to following treatments (1) and (2), the largest length in a horizontal direction of a depression formed on a cut surface in a horizontal direction of a cut site is 5 μm or less:
(1) the copper foil is removed to form a removal site, and
(2) the removal site is irradiated with laser light having a wavelength of 355 nm to form the cut site in a vertical direction of the removal site.
